(19) United States
(12) Patent Application Publication
(10) Pub. No.: US 2015/0206794 A1
(43) Pub. Date: Jul. 23, 2015

(54) Method for Removing Micro Scratches In Chemical Mechanical Polishing Processes

(71) Applicant: TAIWAN SEMICONDUCTOR MANUFACTURING COMPANY, LTD., Hsin-Chu (TW)

(72) Inventors: Yen-Chang Chao, Taichung City (TW); F.I. Chih, Tainan (TW); P.C. Huang, Tainan (TW)

(21) Appl. No.: 14/158,593

(22) Filed: Jan. 17, 2014

(51) Int. Cl. H01L 21/768; H01L 21/02; H01L 21/321

(52) U.S. Cl. CPC H01L 21/76837; H01L 21/3212; H01L 21/76877; H01L 21/7684; H01L 21/02164; H01L 21/02203; H01L 21/02282; H01L 21/02318

(57) ABSTRACT

A chemical mechanical polishing process for manufacturing a semiconductor device includes forming a conductive layer over a first dielectric layer formed over a semiconductor substrate. The conductive layer is patterned to form a patterned conductive layer with a plurality of openings. A second dielectric layer is formed to cover the patterned conductive layer and to fill the plurality of openings. The second dielectric layer is polished to form a planar surface, the planar surface containing micro scratches. A spin-on-glass (SOG) layer is applied over the at least second dielectric layer to fill the micro scratches.

### BACKGROUND

The semiconductor integrated circuit (IC) industry has experienced rapid growth. Technological advances in IC materials and design have produced generations of ICs where each generation has smaller feature sizes and more complex circuits than those from the previous generation.

As IC technology has moved from 130 nanometers (nm) to 20 nm and beyond, planarization techniques, such as chemical mechanical polishing (CMP), are required to selectively remove high elevation features by a combination of mechanical polishing and chemical reaction. A high degree of surface planarity is an important factor in forming high-density devices using a photographic operation. Only a highly planar surface is capable of avoiding undesirable diffraction due to height difference during light exposure, so as to achieve a highly accurate pattern transfer. One disadvantage of CMP processes, however, is that micro scratches may develop on the surface under polishing. This problem is illustrated in FIGS. 1A to 1D that are cross-sectional views showing the progression of manufacturing steps in producing a metallic interconnect that uses CMP according to a conventional method. First, as shown in FIG. 1A, a semiconductor substrate 110 having an inter-layer dielectric (ILD) layer 112 thereon is provided. Then, conductive line layer 114, for example, an aluminum layer, a metallic silicon layer, a doped polysilicon layer or a polysilicon layer is formed over the ILD layer 112. Thereafter, an insulating layer 116 is formed by depositing over the ILD layer 112 and the conductive line layer 114. Due to the presence of the conductive lines 114 underneath, the insulating layer 116 has a pyramid-like cross-sectional profile 118 near its upper surface. In the subsequent step, an inter-metal dielectric (IMD) layer 119 is formed over the insulating layer 116.

Next, as shown in FIG. 1B, a chemical mechanical polishing (CMP) operation is carried out to polish the IMD layer 119 so that a planar upper surface is obtained. Because a CMP method can easily lead to the over-polishing of the surface of the IMD layer 119 or the scratching of the surface by polishing particles, micro scratches will appear on the surface of the IMD layer 119. These micro scratches vary in size and depth, and two such scratches 120a and 120b are shown in FIG. 1B.

Next, as shown in FIG. 1C, conventional photolithographic and etching operations are carried out to pattern the insulating layer 116. Consequently an opening 122 through the insulating layer 116 and the IMD layer 119 is formed. The opening 122 exposes one of the conductive line layers 114 and subsequently will serve as a via.

Next, as shown in FIG. 1D, a metallic layer 126 is formed over the IMD layer 119 and inside the opening 122. Thereafter, photolithographic and etching operations are again carried out to pattern the metallic layer 126, thereby forming second metallic lines 126. Due to the presence of scratches (120a and 120b) on the surface of the IMD layer 119, metal will also be deposited into the scratches forming undesirable metallic scratch lines 124a and 124b.

The metallic scratch lines 124a and 124b can lead to a number of defects. For example, the metallic scratch lines can form a bridge linking up neighboring second metallic lines 126, thereby causing contact or via short circuiting during interconnect formation.

### BRIEF DESCRIPTION OF THE DRAWINGS

Embodiments of the present disclosure are best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1A-1D are cross-sectional views illustrating the progression of manufacturing steps in producing a metallic interconnect that uses chemical-mechanical polishing according to a conventional method.

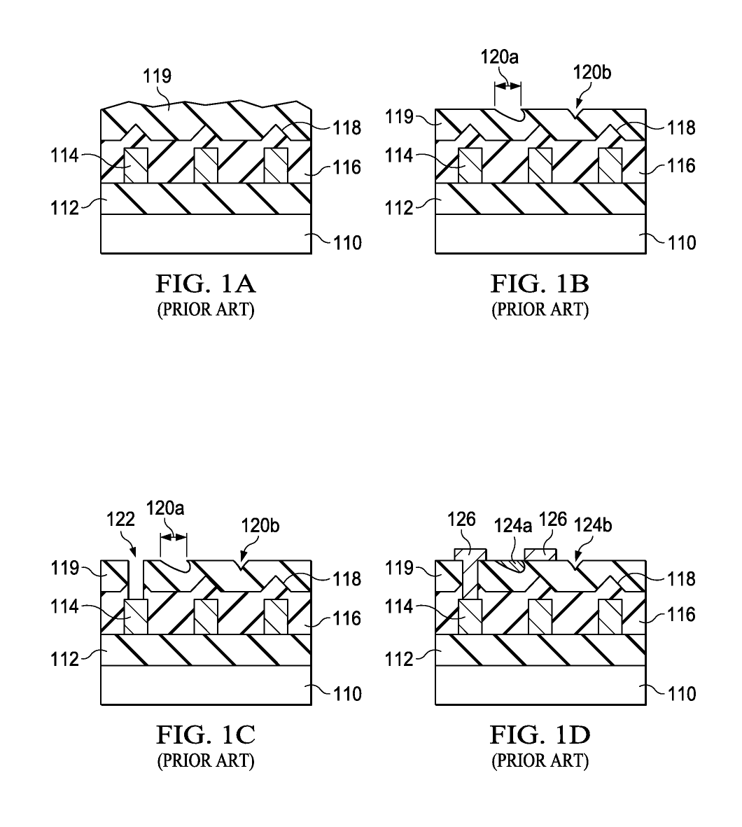

FIG. 2 is a flowchart of a method for removing micro scratches in the manufacture of a semiconductor device according to various embodiments of the present disclosure.

FIGS. 3A-3E are cross-sectional side views showing the progression of manufacturing steps in producing a metallic interconnect that uses chemical mechanical polishing according to one or more embodiments of the present disclosure.

### DETAILED DESCRIPTION

In the following description, specific details are set forth to provide a thorough understanding of embodiments of the present disclosure. However, one having ordinary skill in the art will recognize that embodiments of the disclosure can be practiced without these specific details. In some instances, well-known structures and processes are not described in detail to avoid unnecessarily obscuring embodiments of the present disclosure.

Reference throughout this specification to “one embodiment” or “an embodiment” means that a particular feature, structure, or characteristic described in connection with the embodiment is included in at least one embodiment of the present disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments. It should be appreciated that the following figures are not drawn to scale; rather, these figures are intended for illustration.

One major aspect of the present disclosure is the coating of a spin-on-glass (SOG) layer over the dielectric layer after a chemical mechanical polishing operation is applied to planarize the dielectric layer. Therefore, a higher degree of surface planarity can be obtained, and micro scratches on the surface of the dielectric layer due to over polishing or scratching by polishing particles can be eliminated. Consequently, short circuiting between metallic lines (conductive lines) due to the presence of metallic scratch lines is prevented.

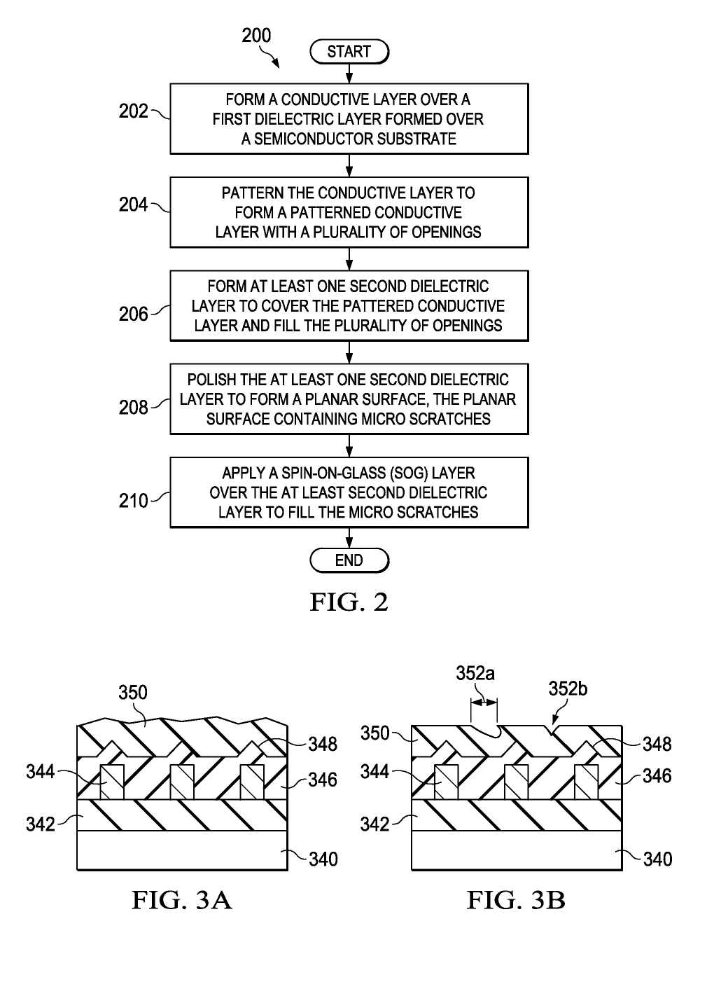

FIG. 2 is a flowchart of a chemical mechanical polishing method 200 for fabricating a semiconductor device according to various aspects of the present disclosure. Referring to FIG. 2, the method 200 includes block 202, in which a conductive layer is formed over a first dielectric layer formed over a semiconductor substrate. The method 200 includes block 204, in which the conductive layer is patterned to form a patterned conductive layer with a plurality of openings. The method 200 includes block 206, in which at least one second dielectric layer is formed to cover the patterned conductive layer and fill the plurality of openings. The method 200 includes block 208, in which the at least one second dielectric layer is polished to form a planar surface, the planar surface containing micro scratches. The method 200 includes block 210, in which a spin-on-glass (SOG) layer is applied over the at least second dielectric layer to fill the micro scratches.

It is understood that additional processes may be performed before, during, and/or after the blocks 202-210 shown in FIG. 2 to complete the fabrication of the semiconductor device, but these additional processes are not discussed herein in detail for the sake of brevity.

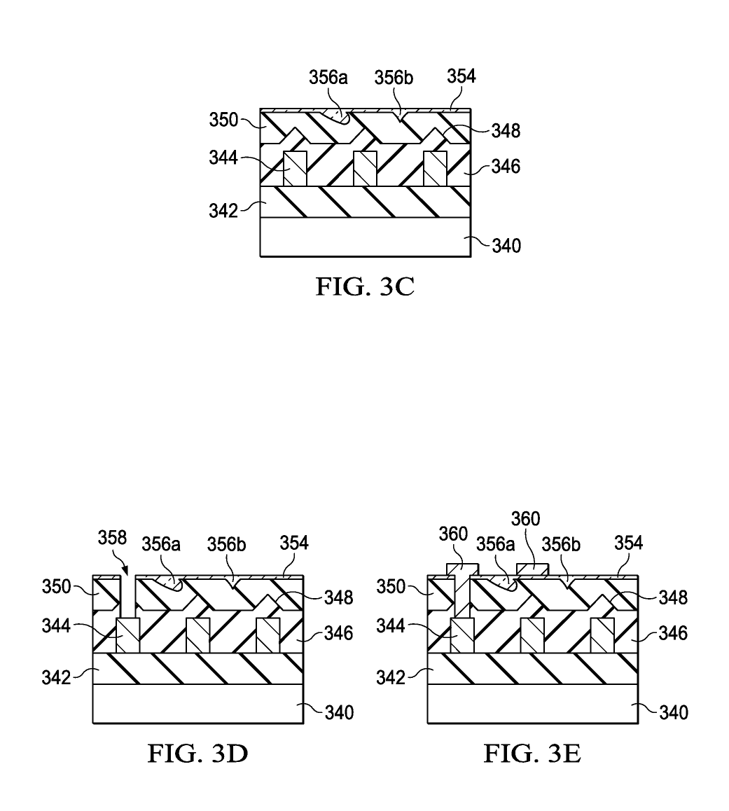

FIGS. 3A, 3B, 3C, 3D, and 3E are cross sectional views showing the progression of manufacturing steps in producing a metallic interconnect that uses chemical mechanical polishing according to one embodiment of the present disclosure. First, as shown in FIG. 3A, a semiconductor substrate 340 is provided. Then, an underlying dielectric layer 342 is formed over the substrate 340. In some embodiments, the underlying dielectric layer 342 is an inter-layer dielectric (ILD) layer. In other embodiments, the underlying dielectric layer 342 is an inter-metal dielectric (IMD) layer. In a subsequent step, first conductive lines 344, for example, aluminum or polysilicon layers are formed over the ILD layer 342. The first conductive lines 344 can be formed by depositing a metallic layer using, for example, a chemical vapor deposition method or a metal sputtering method.

Thereafter, the metallic layer is patterned to form the first conductive lines 344. Next, an insulating layer 346 and a layer to be planarized 350 are formed above the underlying dielectric layer 342 and the first conductive lines 344. The insulating layer 346 is also a dielectric layer formed by depositing silicon oxide, for example over the underlying dielectric layer 342 and the first conductive lines 344 using, for example, a high-density plasma chemical vapor deposition (HDPCVD) method. In some embodiments, due to the presence of the first conductive lines 344 and the characteristic of a HDPCVD deposition, a pyramid-like cross-sectional profile 348 of the insulating layer 346 having a height difference of about 10K Angstroms is formed above each of the first conductive lines 344.

In one or more embodiments, the layer to be planarized 350 is an IMD layer. In some embodiments, the layer to be planarized 350 is an ILD layer. In still other embodiments, the layer to be planarized 350 is a metal layer. Where the layer to be planarized 350 is a layer containing dielectric material, in one or more embodiments, the layer to be planarized 350 is formed by depositing silicon dioxide or a low dielectric constant material such as F-doped silicon oxide (FSG) to a thickness of about 1K Angstroms to 30K Angstroms over the insulating layer 346 using, for example, a plasma-enhanced chemical vapor deposition (PECVD) method. Where the layer to be planarized 350 is a metal layer, in one or more embodiments, the layer to be planarized 350 is formed by depositing a metal such as for example, copper, aluminum, gold, titanium, tungsten, or nickel by a chemical vapor deposition (CVD) method.

Next, as shown in FIG. 3B, a surface of the layer to be planarized 350 is planarized, preferably by polishing using, for example, a chemical mechanical polishing (CMP) method. Because a CMP operation can easily lead to over-polishing of the surface of the layer to be planarized 350 or the scratching of the surface by polishing particles, micro scratches will appear on the surface of the planarized layer 350. Micro scratches can also appear from processes other than CMP, such as etching, photolithography, plasma vapor deposition, chemical vapor deposition, or wafer handling. These micro scratches vary in size and depth, and two such micro scratches labeled 352a and 352b are shown in FIG. 3B.

Next, as shown in FIG. 3C, a liquid film such as a spin-on-glass layer 354 is deposited over the planarized layer 350. The spin-on-glass layer 354, which is applied as a liquid fills the micro scratches 352a and 352b so that micro scratches 352a and 352b are covered. Hence, insulated scratches 356a and 356b are formed.

The spin-on-glass layer 354 represents a major aspect of the present disclosure. The spin-on-glass material can be an inorganic type silicate based SOG. In some embodiments, the spin-on-glass material can be an organic type of siloxane-based SOG. In some other embodiments, the spin-on-glass material is a silicon oxide based polysiloxane SOG. One skilled in the art understands that the molecular weight, the viscosity and the desired film properties of SOG can be modified and adjusted to suit the requirement of specific IC deposition process.

The spin-on-glass layer 354 is deposited on the planarized layer 350 to a thickness in the range of about 100 Angstroms to about 5,000 Angstroms. The substrate 340 is thereafter spun in a spin coating apparatus with a rotational speed which determines the thickness of the spin-on-glass layer desired. In some embodiments, the substrate 340 is spun from around 100 RPM to around 3,000 RPM. After the spin-on-glass layer 354 is evenly applied to the surface of the planarized layer 350, it is cured at a temperature between about 100 degrees Celsius and about 600 degrees Celsius for a time period between about 5 minutes and about 60 minutes. In some embodiments, the spin-on-glass layer 354 is cured at or below atmospheric pressure to enhance solvent outgassing. In some embodiments, the spin-on-glass layer 354 is cured to convert it to substantially silicon dioxide.

In some embodiments, after the curing step, the spin-on-glass layer 354 is etched back to substantially planarize the semiconductor structure and obtain a smooth surface. The etch back process can be carried out in a dry etching technique such as a reactive ion etching technique. In some embodiments, in the etch back process, approximately 1,000 Angstroms thickness of the spin-on-glass layer 354 is removed. In some other embodiments, approximately 500 Angstroms thickness of the spin-on-glass 354 layer is removed.

Next, as shown in FIG. 3D, conventional photolithographic and etching operations are carried out to form an opening 358 through the insulating layer 346, the planarized layer 350 and the spin-on-glass layer 354. The opening 358 exposes one of the first conductive lines 344 and subsequently will serve as a via.

Next, as shown in FIG. 3E, metallic material, for example, tungsten or other conductive material is deposited over the spin-on-glass layer 354 and into the opening 358. Thereafter, photolithographic and etching operations are again carried out to pattern the metallic layer, thereby forming second conductive lines 360. Consequently, a patterned conductive layer with a conductive interconnect structure is formed.

Advantages of one or more embodiments of the present disclosure may include one or more of the following.

In one or more embodiments, a higher quality of polished surface is obtained by eliminating micro scratches on a polished surface, such as an inter-metal-dielectric (IMD) layer, an inter-level dielectric (ILD) layer, or a metal layer.

In one or more embodiments, the polishing process used in the present disclosure is capable of preventing the formation of conductive scratch lines, thereby eliminating possible short-circuiting pathways between subsequently formed conductive lines.

The present disclosure has described various embodiments. According to one embodiment, a chemical mechanical polishing process for manufacturing a semiconductor device includes forming a conductive layer over a first dielectric layer formed over a semiconductor substrate. The conductive layer is patterned to form a patterned conductive layer with a plurality of openings. A second dielectric layer is formed to cover the patterned conductive layer and to fill the plurality of openings. The second dielectric layer is polished to form a planar surface, the planar surface containing micro scratches. A spin-on-glass (SOG) layer is applied over the at least second dielectric layer to fill the micro scratches.

According to another embodiment, in the manufacture of a semiconductor wafer having multiple levels of metallization, a process for removing micro scratches, includes providing a dielectric layer having a substantially planar surface, the dielectric layer containing micro scratches. A spin-on-glass (SOG) layer is applied over the dielectric layer to fill the micro scratches.

According to yet another embodiment, in the manufacture of a semiconductor wafer having multiple levels of metallization, a process for removing micro scratches, includes providing a metal layer over a dielectric layer, the metal layer containing micro scratches. A spin-on-glass (SOG) layer is applied over the metal layer to fill the micro scratches.

In the preceding detailed description, various embodiments have been described. It will, however, be apparent to a person of ordinary skill in the art that various modifications, structures, processes, and changes may be made thereto without departing from the broader spirit and scope of the present disclosure. The specification and drawings are, accordingly, to be regarded as illustrative and not restrictive. It is understood that embodiments of the present disclosure are capable of using various other combinations and environments and are capable of changes or modifications within the scope of the claims and their range of equivalents.

What is claimed is:

1. In the manufacture of a semiconductor wafer having multiple levels of metallization, a process for removing micro scratches, comprising:
providing a dielectric layer having a substantially planar surface, the dielectric layer containing micro scratches; and
applying a spin-on-glass (SOG) layer over the dielectric layer to fill the micro scratches.

2. The process of claim 1, wherein the dielectric layer comprises an inter-layer dielectric (ILD) layer or an inter-metal dielectric (IMD) layer.

3. The process of claim 1, wherein the spin-on-glass layer is applied to a thickness in the range of about 100 Angstroms to about 5,000 Angstroms.

4. The process of claim 1, further comprising:
curing said spin-on-glass layer to substantially convert it to silicon dioxide.

5. The process of claim 4, wherein the spin-on-glass layer is cured at a temperature between about 100 degrees Celsius and about 600 degrees Celsius for a time period between about 5 minutes and about 60 minutes.

6. The process of claim 4, wherein the spin-on-glass layer is cured at or below atmospheric pressure to enhance solvent outgassing.

7. The process of claim 1, wherein the micro scratches are a result of a process selected from the group consisting of chemical mechanical polishing (CMP), etching, photolithography, plasma vapor deposition, chemical vapor deposition, and wafer handling.

8. In the manufacture of a semiconductor wafer having multiple levels of metallization, a process for removing micro scratches, comprising:
providing a metal layer over a dielectric layer, the metal layer containing micro scratches; and
applying a spin-on-glass (SOG) layer over the metal layer to fill the micro scratches.

9. The process of claim 8, wherein the micro scratches are a result of a process selected from the group consisting of chemical mechanical polishing (CMP), etching, photolithography, plasma vapor deposition, chemical vapor deposition, and wafer handling.

10. The process of claim 8, wherein the spin-on-glass layer is applied to a thickness in the range of about 100 Angstroms to about 5,000 Angstroms.

11. The process of claim 10, further comprising:
curing said spin-on-glass layer to substantially convert it to silicon dioxide.

12. The process of claim 11, wherein the spin-on-glass layer is cured at a temperature between about 100 degrees Celsius and about 600 degrees Celsius for a time period between about 5 minutes and about 60 minutes.

13. The process of claim 11, wherein the spin-on-glass layer is cured at or below atmospheric pressure to enhance solvent outgassing.

14. A chemical mechanical polishing process for manufacturing a semiconductor device, comprising:
forming a conductive layer over a first dielectric layer formed over a semiconductor substrate;
patterning the conductive layer to form a patterned conductive layer with a plurality of first openings;
forming at least one second dielectric layer to cover the patterned conductive layer and to fill the plurality of first openings;
polishing the at least second dielectric layer to form a planar surface, the planar surface containing micro scratches; and
applying a spin-on-glass (SOG) layer over the at least second dielectric layer to fill the micro scratches.

15. The chemical mechanical polishing process of claim 14, further comprising:
patterning the spin-on-glass layer and the at least one second dielectric layer to form a plurality of second openings; and
forming conductive vias in the plurality of second openings.

16. The chemical mechanical polishing process of claim 14, wherein the spin-on-glass layer prevents metal bridges from forming in the micro scratches of the at least one second dielectric layer.

17. The chemical mechanical polishing process of claim 14, wherein the spin-on-glass layer provides a higher degree of surface planarity than the planar surface, and further forms a highly planar surface that reduces undesirable diffractions from height differences so that during a subsequent photolithographic operation undesirable diffractions from height differences are reduced.

18. The chemical mechanical polishing process of claim 14, further comprising:
curing said spin-on-glass layer to substantially convert it to silicon dioxide.

19. The chemical mechanical polishing process of claim 18, wherein the spin-on-glass layer is cured at a temperature between about 100 degrees Celsius and about 600 degrees Celsius for a time period between about 5 minutes and about 60 minutes.
